(19) United States
(12) Patent Application Publication
(10) Pub. No.: US 2009/0087663 A1
(43) Pub. Date: Apr. 2, 2009

(54) Free-standing metallic micromechanical structure, method of manufacturing the same, resonator structure using the same, and method of manufacturing a resonator structure using the same

(75) Inventor: Yun Park, Seoul (KR)

Correspondence Address: HARNESS, DICKEY & PIERCE, P.L.C., P.O. BOX 8910, RESTON, VA, 20195, US

(73) Assignees: SAMSUNG ELECTRONICS CO., LTD.; SEOUL NATIONAL UNIVERSITY INDUSTRY FOUNDATION

(21) Appl. No.: 12/149,407

(22) Filed: May 1, 2008

(30) Foreign Application Priority Data
Sep. 28, 2007 (KR) 10-2007-0097693
Sep. 28, 2007 (KR) 10-2007-0097707

(51) Int. Cl. B32B 15/04; B05D 5/12; G03C 5/08; G03F 7/16; C23C 14/34

(52) U.S. Cl. 428/408; 427/77; 430/296; 430/311; 204/192.1

(57) ABSTRACT

Disclosed herein may be a free-standing metallic micromechanical structure having a metal thin film on a carbon nanotube network template (CNTnt), which may include a bilayer laminate obtained by laminating the metal thin film to a predetermined or given thickness on the CNTnt, a manufacturing method thereof, a resonator structure using the same, and a method of manufacturing a resonator structure using the same.

### PRIORITY STATEMENT

This non-provisional application claims priority under U.S.C. § 119 to Korean Patent Applications Nos. 2007-97693, and 2007-97707, both filed on Sep. 28, 2007, the entire contents of which are incorporated herein by reference.

### BACKGROUND

1. Field

Example embodiments are directed to a free-standing metallic micromechanical structure having a metal thin film formed on a CNTnt (carbon nanotube network template), a manufacturing method thereof, and a resonator structure and method of manufacturing a resonator structure using the same, and, more particularly, to a free-standing metallic micromechanical structure having a metal thin film formed on a CNTnt, which comprises a bilayer laminate obtained by laminating the metal thin film to a predetermined or given thickness on the CNTnt, to a method of manufacturing the same, and to a resonator structure and method of manufacturing the resonator structure using the same.

2. Description of the Related Art

CNTs (carbon nanotubes) have increased strength and cross-sectional areas on the scale of ones of nanometers, and have both metallic properties and semiconductor properties, and thus may be effectively applied in various fields. Recently, electrical and mechanical properties, which may be exhibited by mixing CNTs with other materials, are receiving attention.

As one of the main commercial applications of CNTs, a CNT-polymer interface field, in which metallic CNTs may be incorporated into a polymer matrix in order to increase electrical conductivity, may be an example. Another application field may be related to CNT-metal interfaces. In particular, there may be some reports regarding the mechanical properties of CNT-metal compounds, and as well, electronic structures for realizing effective ohmic contact.

Because such CNTnt-metal compounds manifest electrical and thermodynamic properties and increased strength, they may be variously applied as material for devices including electrical conductor metal lines and microelectromechanical system (MEMS) or nanoelectromechanical system (NEMS) structures.

Further, with the recent development of upward and downward fabrication techniques in MEMS- and NEMS-related devices, thorough research into NEMS having higher resonance frequency as a result of decreased mass and size is being conducted to measure minimum force and displacement. In addition, with the goal of realizing the MEMS and NEMS structures using only metal, the mechanical properties of pieces of metal having decreased dimensions are receiving attention. In particular, restoration from plastic deformation for Al and Au free-standing thin films may be reported, along with the essential increase in yield strength of Au nanowires. However, metal films have higher ductility than monocrystalline semiconductors and oxides thereof, and therefore, metallic NEMS resonators may be devised to find means for effectively mixing metal and widening the dynamic range from the noise floor to non-linear behavior.

### SUMMARY

Example embodiments provide a free-standing metallic micromechanical structure having a metal thin film on a carbon nanotube network template (CNTnt), wherein the metal thin film may be laminated to a predetermined or given thickness on the CNTnt.

Example embodiments also provide a method of manufacturing a free-standing metallic micromechanical structure including forming a CNTnt on a substrate, and forming a metal thin film on the CNTnt. Example embodiments also provide a resonator structure including the free-standing metallic micromechanical structure and a method of manufacturing a resonator structure using the same.

### BRIEF DESCRIPTION OF THE DRAWINGS

Example embodiments will be more clearly understood from the following detailed description taken in conjunction with the accompanying drawings. FIGS. 1-8(c) represent non-limiting, example embodiments as described herein.

FIG. 1 illustrates a schematic view of a free-standing metallic micromechanical structure having a metal thin film formed on a CNTnt, according to example embodiments;

FIG. 2 illustrates a schematic view of a process of forming a linker-free assembly of swCNTs on a semi-insulator (SI) GaAs (001) substrate, according to example embodiments;

FIG. 3 shows AFM images of the linker-free assembly of swCNTs on a GaAs substrate, including an SEM image of Al/CNTnt for a 0.41 nm thick CNTnt layer, according to example embodiments;

FIG. 4(a) shows a schematic view of a process of manufacturing Al/CNTnt doubly-clamped beams, including forming a linker-free assembly of swCNTs on a substrate, forming a doubly-clamped beam form thereof through e-beam lithography and photolithography, and then performing sputtering deposition of Al and lift-off thereof, and performing electrical connection for dynamic flexural measurement, FIG. 4(b) shows an AFM image of a CNTnt having an effective thickness of 0.41 nm, corresponding to the surface after the step (i), FIG. 4(c) shows an FE-SEM image of the Al/CNTnt corresponding to the surface after the step (ii), FIG. 4(d) shows an FE-SEM image of the suspended CNTnt to depict the actual CNTs mixed with beams from a test sample, FIG. 4(e) shows a color SEM image of two doubly-clamped Al/CNTnt beams (including Al having a width of 3 μm, a length of 23 and 26 μm, and a thickness of 50 nm) and of an Al/CNTnt layer, and FIG. 4(f) shows specific Al/CNT beams (100 nm×3 μm×17 μm) after measurement of spectrum response, in which a first fundamental oscillation mode may be demonstrated by xy optical scanning of a sample holder during the application of a predetermined electrostatic waveform of a resonance oscillation frequency fₒ (20.88 MHz);

FIG. 5 shows a schematic view of a construction for dynamic flexural measurement;

FIG. 6 shows dynamic flexural responses in the vicinity of a first fundamental mode for doubly-clamped beams of Al(a-c) and Al/CNTnt (d-f) in the same dimension (50 nm×3 μm×14 μm);

FIGS. 7(a), 7(b), and 7(c) show plots of resonance frequency fₒ versus beam length l for 100 nm Al (represented by a red circle) and Al/CNT (represented by a blue circle) resonators having a width of 2 μm and 3 μm, for 50 nm Al and Al/CNTnt resonators having a width of 2 μm, and for 50 nm Al/CNTnt resonator having a width of 3 μm, respectively; and

FIG. 8(a) shows a schematic view of force deflection spectroscopy, FIG. 8(b) shows a force deflection curve for Al beams (100 nm×3 μm×17 μm), and FIG. 8(c) shows a force deflection curve for Al/CNTnt beams (100 nm×3 μm×22 μm).

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Hereinafter, a detailed description will be given of example embodiments with reference to the accompanying drawings. Reference now should be made to the drawings, in which the same reference numerals are used throughout the different drawings to designate the same or similar components. In the drawings, the thicknesses and widths of layers are exaggerated for clarity. Example embodiments may, however, be embodied in many different forms and should not be construed as limited to the example embodiments set forth herein. Rather, these example embodiments are provided so that this disclosure will be thorough and complete, and will fully convey the scope of example embodiments to those skilled in the art.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Example embodiments may be directed to a free-standing metallic micromechanical structure having a metal thin film formed on a CNTnt, a method of manufacturing the same, and a resonator structure using the same.

In accordance with example embodiments, the free-standing metallic micromechanical structure having a metal thin film formed on a CNTnt may include a bilayer laminate obtained by depositing a metal thin film, for example, an Al thin film, to a predetermined or given thickness, for example, a thickness of about 50˜about 100 nm, on a CNTnt having a predetermined or given thickness, for example, a thickness of about 0.41 nm or less. In accordance with example embodiments, the method of manufacturing the free-standing metallic micromechanical structure having a metal thin film formed on a CNTnt may include forming a CNTnt on a substrate.

According to the manufacturing method of example embodiments, a free-standing metallic micromechanical structure having a predetermined or given width and a predetermined or given length, for example, a width of about 2˜about 3 μm and a length of about 5˜about 50 μm, may be realized, and a method of fabricating suspended doubly-clamped beam microresonators may be realized. For example, the suspended doubly-clamped beams may be realized from the bilayer laminate formed through the thin film deposition of Al (about <100 nm). The substrate may be a semiconductor substrate.

In accordance with example embodiments, the resonator structure may be provided using the free-standing metallic micromechanical structure having a metal thin film formed to a predetermined or given thickness on a CNTnt. For example, the above structure may be specified as a suspended doubly-clamped beam microresonator structure having a predetermined or given width and a predetermined or given length, for example, a width of about 2˜about 3 μm and a length of about 5˜about 50 μm. In accordance with example embodiments, a method of manufacturing the resonator structure may include forming a metal thin film on a CNTnt which may include a bilayer laminate obtained by depositing a metal thin film, for example, an Al thin film, to a predetermined or given thickness, for example, a thickness of about 50˜about 100 nm, on a CNTnt having a predetermined or given thickness, for example, a thickness of about 0.41 nm or less.

From dynamic flexural measurement and the application of continuum mechanics, mechanical non-linear behaviors may be suppressed and the effective Young's modulus (˜about 280±50 GPa) may be about two times or more than that of aluminum (Al) deposited on a CNTnt. Such measurement values match the results of measurement of force-deflection spectroscopy performed using an AFM cantilever tip or by quasi-static flexural measurement.

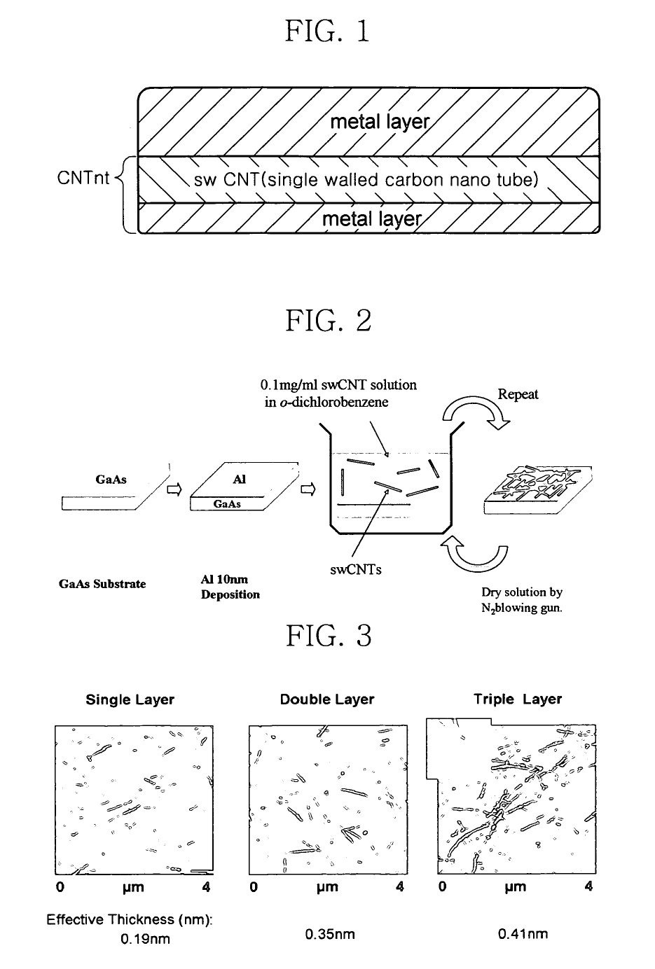

FIG. 1 illustrates the bilayer laminate structure having the metal thin film formed to a predetermined or given thickness on the CNTnt. The CNTnt may be formed by laminating a self assembly of CNTs on a metal thin film layer. The illustrated structure may be applied to various devices, including microresonators, through which the elastic modulus and yield strength of the device may be improved, and furthermore, the dynamic range may be widened.

Below, the self-assembly process of the CNTnt may be described in detail. According to the self-assembly process of the CNTnt illustrated in FIG. 2, metal may be laminated to a predetermined or given thickness on the surface of an epi-ready semi-insulator GaAs (001) substrate, for example, aluminum (Al) about 10 nm thick may be laminated through sputtering deposition. Thereafter, the substrate may be placed in an about 0.1 mg/ml solution of a room-temperature o-dichlorobenzene solvent and swCNTs (single walled carbon nanotubes) having a predetermined or given length, for example, a length of about 2˜about 3 μm. The substrate may be then removed from the solution, after which the sample may be dried in liquid nitrogen. As illustrated in FIG. 3, the above process may be repeated, so that a single layer having an effective thickness of about 0.19 nm, a double layer (about 0.35 nm), and a triple layer (about 0.41 nm) may be formed, thereby obtaining a desired CNTnt. On the CNTnt thus obtained, metal, for example, Al, may be further laminated to a thickness of about 50˜about 100 nm through sputtering deposition, consequently realizing a free-standing metallic micromechanical structure in which the metal thin film may be formed to a predetermined or given thickness on the CNTnt.

Below, for a more detailed description of the free-standing metallic micromechanical structure in which the metal thin film may be formed to a predetermined or given thickness on the CNTnt, the process of manufacturing the resonator structure using the free-standing metallic micromechanical structure in which the metal thin film may be formed to a predetermined or given thickness on the CNTnt and the dynamic measurement of the structure may be explained, thereby more definitively disclosing the free-standing metallic micromechanical structure having the metal thin film formed on the CNTnt.

The microresonator may includes the bilayer laminate in which a metal thin film, for example, an Al thin film, may be deposited to a predetermined or given thickness, for example, a thickness of about 50˜about 100 nm, on a CNTnt having a predetermined or given thickness, for example, a thickness of about 0.41 nm or less, on a semiconductor substrate, for example, a GaAs substrate. The particular case where the metal thin film may be formed of aluminum (Al) may be taken as an example.

The Al and Al/CNTnt resonators have dynamic and quasi-static properties. In terms of dynamic properties, the resonator may be driven in a sine waveform with sufficient amplitude and bias to reach non-linear responses for electrostatic resonance. In terms of quasi-static properties, AFM cantilever tips may be used, so that the suspended beams may be bent, in the course of recording the force and displacement.

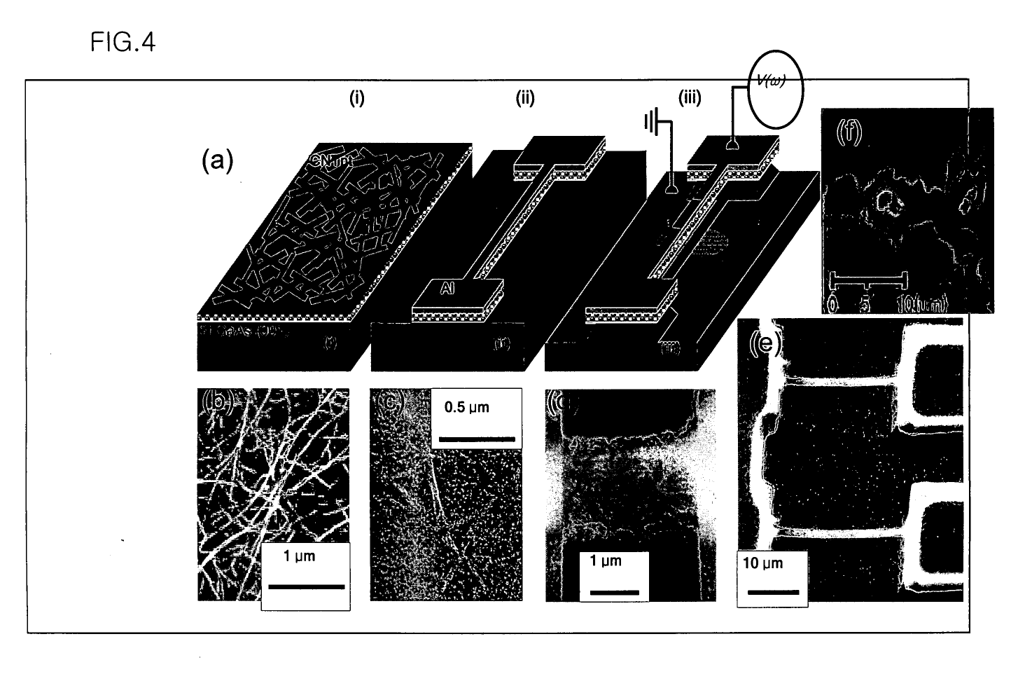

FIG. 4(a) schematically shows the process of manufacturing Al/CNTnt doubly-clamped beams, including forming a linker-free assembly of swCNTs on a substrate, forming a doubly-clamped beam form thereof through e-beam lithography and photolithography, and then performing sputtering deposition of Al and lift-off thereof, and performing electrical connection for dynamic flexural measurement. FIG. 4(b) shows the AFM image of the CNTnt having an effective thickness of about 0.41 nm corresponding to the surface after forming the linker-free assembly of swCNTs on a substrate, FIG. 4(c) shows the FE-SEM image of the Al/CNTnt corresponding to the surface after forming the doubly-clamped beam, and FIG. 4(d) shows the FE-SEM image of the suspended CNTnt to depict the actual CNTs mixed with beams from the test sample. FIG. 4(e) shows the color SEM image of two doubly-clamped Al/CNTnt beams (including aluminum (Al) having a width of about 3 μm, a length of about 23 and about 26 μm, and a thickness of about 50 nm) and of an Al/CNTnt layer. Also, FIG. 4(f) shows specific Al/CNT beams (100 nm×3 μm×17 μm) after the measurement of a spectrum response, in which a first fundamental oscillation mode may be demonstrated by xy optical scanning of a sample holder during the application of a predetermined or given electrostatic waveform of resonance oscillation frequency fₒ (about 20.88 MHz). Further, the shape of the suspended doubly-clamped beams illustrated in these drawings may be not limited thereto. Thus, without departing from the scope of the example embodiments, the shape of the beams may be variously modified. The shape of the beams may be patterned in various shapes in the step of forming the doubly-clamped beam form through e-beam lithography and photolithography.

The free-standing MEMS and NEMS structures may be realized using etch-selective materials. Although most CNTs may be chemically inert, relatively large numbers of acid-based Si series etchants may function to more easily remove metal, and thus GaAs may be used as the substrate to manufacture the microresonator (FIG. 4(a)). The Al and Al/CNTnt microresonators may be realized through similar methods. On the GaAs substrate, an Al thin film layer (having a thickness of about 10 nm) may be formed using UHV sputtering to facilitate the formation of the linker-free assembly of swCNTs in order to form the CNTnt (FIG. 4(b)).

The sputtering deposition of the Al thin film may be conducted three times so as to realize the doubly-clamped Al/CNTnt resonator. The above process may be carried out for the improvement of the self assembly of the CNTnt (having a predetermined or given thickness, for example, a thickness of about 10 nm or less) the first time, for the formation of the bilayer laminate (having a predetermined or given thickness, for example, a thickness of about 50˜about 100 nm) including Al as a constituent element the second time, and for the formation of a counter electrode (having a predetermined or given thickness, for example, a thickness of about 5 nm or less) the third time. As such, the sputtering conditions therefore follow.

After the background pressure reaches about ˜2.4×10⁻⁷ torr, the sample may be placed in a sputtering chamber through a load lock. In the course of sputtering, background argon (Ar) (about 99.999%) pressure of about 4 mTorr may be maintained. The sample holder may be thermally connected with the chamber. The Al target on a DC magnetron source may be sputtered at about 100 W at a deposition rate of about 0.335 nm/sec. The deposition rate and the thin film thickness may be measured by profilometry and AFM (Digital Instruments NanoScope IIIa). The deposition of Al may be not limited to sputtering deposition.

In the above procedure, thermal stress may be evaluated. The linear thermal expansion coefficients α for Al and GaAs may be about 23.1×10⁻⁶ K⁻¹ and about 5.8×10⁻⁶ K⁻¹, respectively. Supposing that ΔT may be about 10 K during the deposition of about 3 minutes, in-plane stress depending on the changes in temperature may be expressed as

$${σ}_{T} = \frac{{E}_{Al}}{1 - {v}_{Al}} ( {α}_{Al} - {α}_{GaAs} ) Δ T .$$

If bulk values of Young's modulus (about 70 GPa) and Poisson ration (about 0.35) of Al may be applied, σ_{T} may be ˜18 MPa. The value thus evaluated may be approximate to the internal stress value adjusted from an about 50 nm Al doubly-clamped beam structure. In the actual film, total internal stress in the thin film may include thermal stress and morphology.

Below, the self-assembly method of a CNTnt and the manufacturing method of doubly-clamped beams may be specifically described. However, the units used for the methods may be given merely for the purpose of illustration and may not be construed as limiting the scope of example embodiments.

The linker-free assembly of CNTs may be illustrated in FIG. 2. The surface of the epi-ready semi-insulator GaAs (0010) substrate may be manipulated through sputtering deposition of Al about 10 nm thick, after which the substrate may be placed in an about 0.1 mg/ml solution of a room-temperature o-dichlorobenzene solvent and swCNTs having a length of about 2˜about 3 μm. The substrate may be removed from the solution, after which the sample may be dried in liquid nitrogen. As seen in FIG. 3, the above procedure may be repeated in order to form a single layer having an effective thickness of about 0.19 nm, a double layer (about 0.35 nm), and a triple layer (about 0.41 nm).

After the formation of the CNTnt having a thickness of ˜0.41 nm, the doubly-clamped beam shape may be patterned through standard e-beam lithographic and photolithographic techniques. Subsequently, using sputtering deposition of Al and lift-off thereof, the microresonator may be patterned. The residual CNTs may be eliminated through reactive ion etching using the patterned beams acting as a self-aligning etch mask. The beam resonator may be suspended from the substrate using a dilute citric acid/hydrogen peroxide solution, which may be an isotropic GaAs chemical etchant. Where the GaAs etchant may be used, both Al and CNT may be proven to be chemically inert. Immediately after the etching, the sample may be dried through a critical point drying technique. Finally, an about 5 nm thick Al bottom counter electrode layer may be deposited. (FIGS. 4(c) to 4(e)).

For example, after the formation of the linker-free assembly of swCNTs, in order to pattern an NEMS resonator structure along the electrical lead and to eliminate a bilayer resistor system (copolymer about 300 nm thick and polymethyl methacrylate (PMMA) about 500 nm thick), e-beam lithography with thermal emission SEM, using Nabity NPGS for rasterization of e-beams, may be employed. The resonator structure may be formed in a solution of MIBK/IPA (Methyl Isobutyl Ketone/Isopropyl Alcohol) at about 1:3, rinsed with IPA, and then dried over N₂, after which Al sputtering deposition (thickness of about 50 or about 100 nm)) may be further conducted, and then doubly-clamped beams and corresponding electrical leads may be subjected to lift-off in acetone, thus forming a desired pattern. Subsequently, the CNT layer, which may be latent and may be exposed, may be eliminated through reactive ion etching using SF₆ (˜100 mTorr) at about 75 W. The suspension of the metal/CNT NEMS structure from the GaAs substrate may be realized with the use of a standard etchant for GaAs, which may be proven to have almost no influence on CNTs and metal, which may be used in the above procedure. For etching of the GaAs layer, an example of a wet etchant may include a mixture of citric acid/hydrogen peroxide (about 5:1). For etch-stop, even when a hetero structure layer may not be formed on the substrate, the etching process may be controlled by normalized etching rate (˜300 nm/min) and etching time. After the etching process, critical point drying may be performed to minimize or reduce undesirable effects due to surface tension of the solution in the course of deposition. Thereafter, a wedge bonder may be used to electrically connect the beams using Al wires.

For dynamic measurement, the microresonator may be electrostatically driven by a function generator for outputting a sine waveform (Vₒ=V_{DC}+V_{AC} sin ωt) having variable frequency, amplitude, and bias. The time-varying displacement response of the microresonator may be optically detected at the place where a microresonator acts as a mirror in a construction similar to a standard Michelson interferometer. The other leg of the interferometer, having a beam splitter at the center thereof, may include a high-bandwidth optical detector, which may be read by a fixed mirror and a lock-in amplifier, at an initial position changeable by a piezoelectric actuator having a resolution of ones of nm.

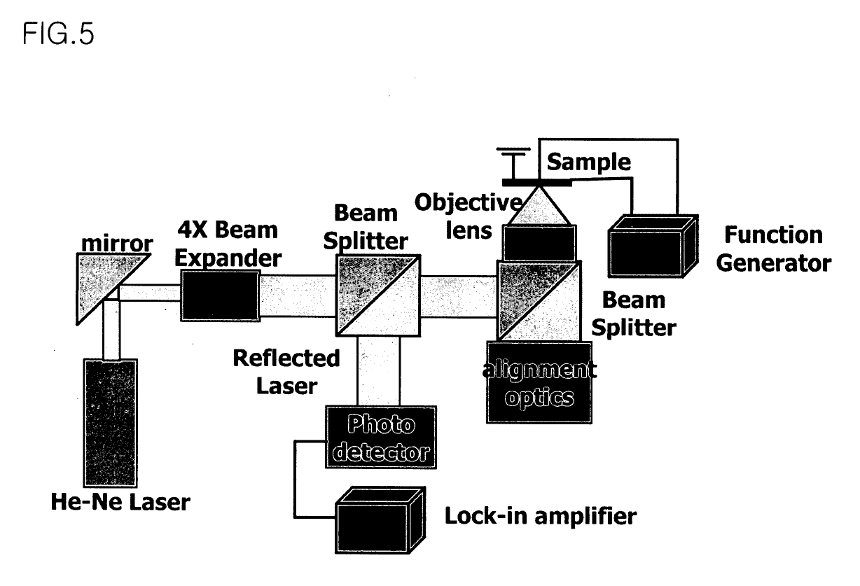

The dynamic measurement of the doubly-clamped beams follows. When a voltage signal having a specific frequency may be applied between the doubly-clamped beams and the substrate, the mechanical structure may be driven at the intended frequency. If the driving force interferes with the fundamental frequency of the dynamic mode, beams may be oscillated on the nanometer scale. Such displacement may be observed through measurement using the optical interferometer (FIG. 5). Upon dynamic measurement, laser beams may reach the surface of the sample and may be reflected by the suspended resonator. As the suspended resonator may be moved, the focus of the objective lens may be shifted from the surface of a paddle, and the reflected beams may be radially emitted. Thus, the displacement of the NEMS resonator structure may be changed into the form of Gaussian beams. The changes in the form of laser beams may affect the intensity of incident beams, which are detected by the optical detector. The optical detector may function to sense the difference in optical intensity between an incident laser and reflected laser from the photodiode. From this standpoint, when the resonator may be driven by AC bias corresponding to the resonance frequency thereof, the changes in position may have an influence on the electrical signal from the optical detector. Using an RF rock-in amplifier, relatively small changes in output voltage may be sensed. For optical construction including the fixed mirror, an about 10 mW He—Ne laser may be used. The force per unit length of about 13.5 μN/m in response to the driving signal of about 10 V may be applied to beams. The optical measurement may be conducted at about room temperature in an appropriate vacuum state (˜100 Pa).

The spectrum response ranging from about 100 kHz to about 80 MHz may represent an inevitable overhang response near the beam clamp, due to the flexural response of the beams in the fundamental mode and high harmonics and underetching of less than about 2 μm. The resonators may be located at respective laser spots, so that the properties derived from the beams may be demonstrated. Whether the intensity of the optical detector may be maximized or increased at the center of the beams, as expected, may be determined by a given resonance frequency corresponding to the fundamental mode may be observed (FIG. 4(f)). In the given geometrical structure, the Al/CNTnt resonator may have a higher resonance frequency than the Al resonator. The response may be adequate for a Lorenz function in the range of about 110˜about 190 Q-factor without any statistical distinction between Al/CNT and Al resonators. In this case, the attenuation mechanism depending on the geometrical structure and surrounding environment may be considered more important than any internal energy loss mechanism.

In similar dimension and force, the difference in effective Young's modulus E may easily explain the difference in ωₒ. For actual purposes, the effective volume of CNT may be less than about 1%, on the assumption that the thickness and density may be similar.

For a forced harmonic resonator, the following equation may be represented.

$$m \frac{{\partial }^{2} z}{\partial t} + γ \frac{\partial z}{\partial t} + kz = {F}_{o} cos ω t$$

wherein m may be the mass, γ may be the attenuation coefficient, and Fₒ may be the magnitude of time-varying force. Coordinates in which the beam axis may be an X axis and the oscillation axis may be a Z axis may be selected.

In order to determine the amplitude of oscillation,

$$\vert Z \vert = {\frac{{F}_{0}}{m} [ {( {ω}^{2} - {ω}_{o}^{2} )}^{2} + {( {ωω}_{0} / Q )}^{2} ]}^{- \frac{1}{2}}$$

is provided, in which Z̅(ω) is a Lorenz function having an actual number part. As such, ωₒ=\sqrt{k/m}, and Q=ωₒm/γ.

Subsequently, the kinetic equation

$$EI \frac{{\partial }^{4} Z}{\partial {x}^{4}} - {σ}_{int} \frac{{\partial }^{2} Z}{\partial {x}^{2}} = - ρ A \frac{{\partial }^{2} Z}{\partial {t}^{2}}$$

may be applied, in which I may be the 2^{nd} inertia momentum, σᵢₙₜ may be the internal stress in the structure, and A may be the transverse cross-sectional area. Recently, σᵢₙₜ may play an important role in the nanomechanical resonator.

Subsequently, in consideration of boundary conditions suitable for beams having a length of L, ωₒ for the thin film beams having an effective spring constant k and a thickness t may be represented by the following equations.

k=Mωₒ² Equation 1

$${ω}_{0} = 1.03 \frac{t}{{L}^{2}} \sqrt{\frac{E}{ρ}} \sqrt{1 + \frac{{σ}_{int} {L}^{2}}{3.4 {Et}^{2}}} \qquad Equation 2$$

The above equations may be effective in the linear range. In consideration of the geometrical structure, non-linearity may be based on an electrical term affecting a dynamic term and a forcing term. In the former case, the gradient of the σ-ε curve may be increased in proportion to the amplitude at which the restoring force increases, and thus may be non-linear for a relatively large strain. In the latter case, the gradient may be non-linear for variation from a simple parallel capacitor model. In particular, the case of a geometrical structure similar to a suspended cable having a ratio of sag to length much lower than about 1 results in ωₒ∝L⁻¹, like a taut string, as in the case of σᵢₙₜ>>E.

As the amplitude of time-dependent forcing term may be increased, the signal of the optical detector corresponding thereto may be increased. In the predetermined or given amplitude, in the case of the Al microresonator, a significant shift or increase may be observed at the frequency fₒ related to maximum or increased displacement during the application of the same force. The shift at the frequency may be decreased in the Al/CNTnt resonator. This may be considered to be due to the non-linear response of the beams. Generally, non-linear spring force may be expressed as F=−kx−k₁x²−k₂x³+O(x⁴), in which k may be the linear spring constant (Equation 1), and kₙ may be the n^{th} correction. In this case, k=k^{m}+k^{e}, k^{m}>0, k^{e}<0. In consideration of only non-linear behavior caused from the mechanical or electrical term, V_{DC}=0,

$$m \frac{{\partial }^{2} z}{dt} + γ \frac{\partial z}{\partial t} + kz + {k}_{1} {z}^{2} + {k}_{2} {z}^{3} = {F}_{o} cos ω t$$

results. In the first mechanical correction, k₁^{m}=0, and, in the electrical/capacitance correction, k₁^{e}≈0 for V_{DC}=0. In the case of k₁≈0, an equation defined by a Duffing oscillator may be employed. This may be explained by the NEMS doubly-clamped resonator for novel sensor detection and signal processing. Whether fₒ may be increased to V_{AC} (hardening) or decreased (softening) may be dependent on k₂ signals. Because the electrostatic force may be geometrically dependent and may be almost the same, the force term for Al and Al/CNTnt microresonators may be retarded by mechanical restoring force (or displacement from the equilibrium position) depending on the effective E.

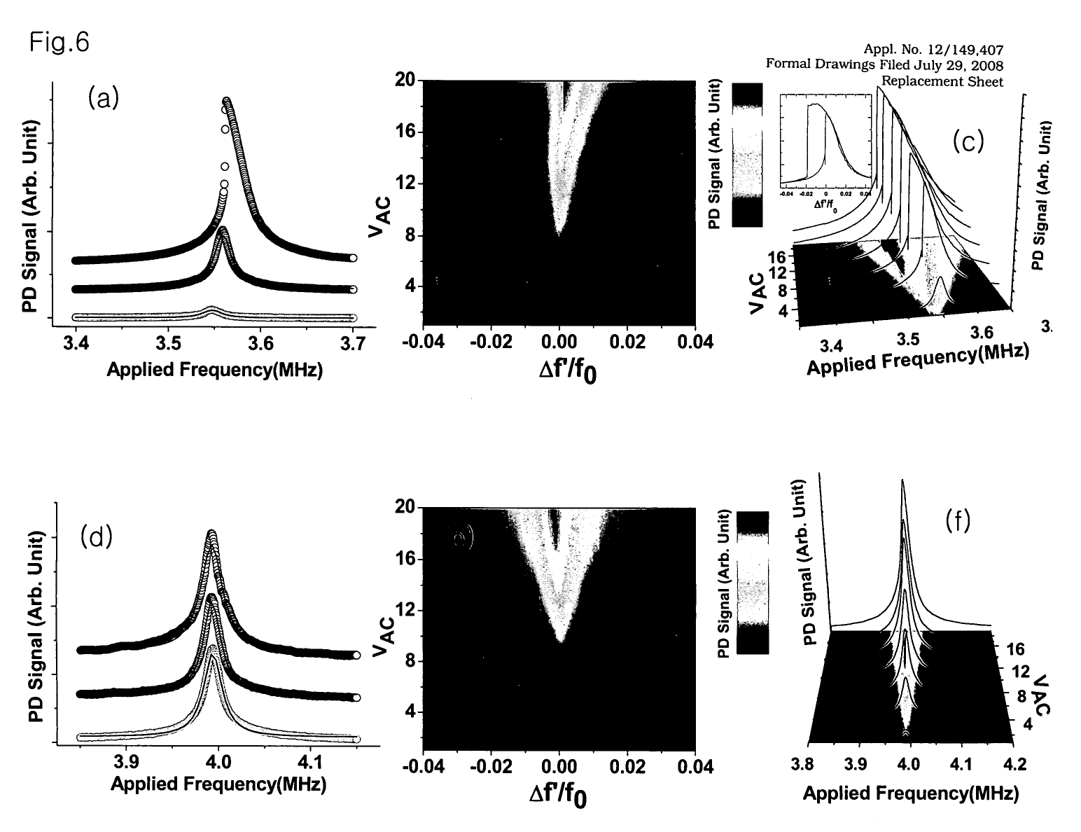

FIG. 6 shows the dynamic flexural responses near the first fundamental mode for doubly-clamped beams of Al (a-c) and Al/CNTnt (d-f) in the same dimension (50 nm×3 μm×14 μm). In the case where V_{AC} may be low and V_{DC} equals 0 (a, b, d, e), a measurement point, which may be to be applied to a Lorenz function, may be found. For Al beams having increasing force amplitude (V_{AC}=4, 10 and 19), the response may be asymmetry having hardening (b), whereas the case of Al/CNTnt may be symmetry having softening (e). Such behavior manifests mechanical non-linearity which determines the Al doubly-clamped beams. In the case where V_{DC} equals to 5, the non-linear response may be more evident for Al beams (c) compared to for Al/CNTnt beams (e). The displacement of Al beams under almost the same driving electrostatic force may be mechanically larger than Al/CNTnt. This difference may be increased by the mechanical non-linear ‘hardening’ response of Al beams. Although the calculation of k₂^{m} using the deformation theory may be very difficult, quantitative analysis of the accurate value of E may be realized from the above response, but focus may be imposed on the response frequency of the first flexural mode. The change in the ratio of the length to the width of beams given may be compared, which demonstrates that ωₒ may be highly dependent on L. When the thickness of Al may be changed to about 50˜about 100 nm for about 100 nm Al/CNTnt and Al resonators, the case of L>20 μm may be ωₒ∝L⁻² but the case where L<about 20 μm may be ωₒ∝L⁻¹. In contrast, ωₒ of about 50 nm Al/CNTnt and Al resonators may be more easily substituted into Equation 2.

As such, that non-linearity may be showed indicates the change in Young's modulus, because Al may be moved or may be subjected to a relatively large external force to thus result in larger flexure. However, the case of the Al/CNTnt may maintain uniform strength even when great movement or great force may be applied, as in Al. As a result, non-linearity may disappear in Al/CNTnt, and thus, Al/CNTnt may be stronger than Al.

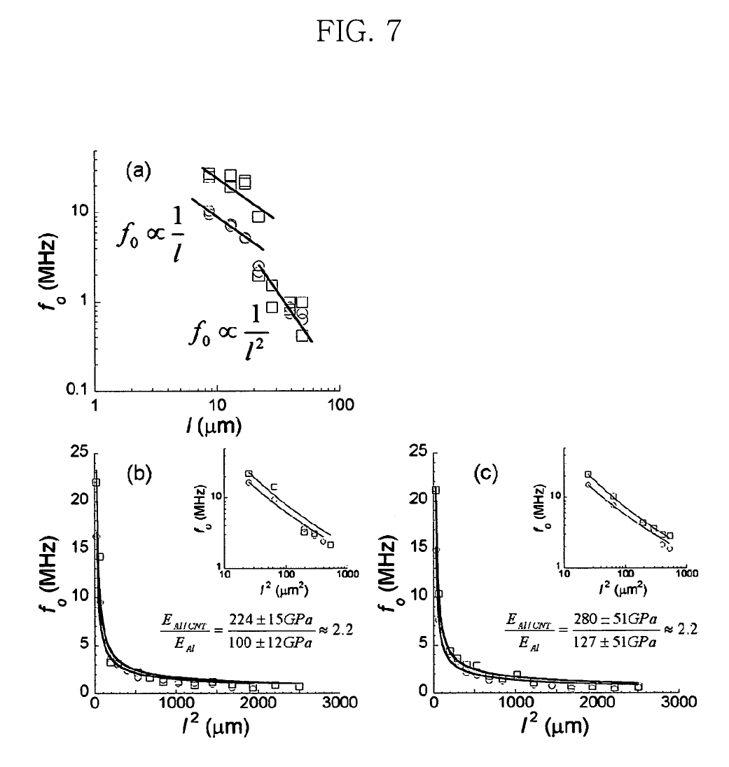

FIGS. 7(a), 7(b), and 7(c) show the plots of resonance frequency fₒ versus beam length l for the about 100 nm Al (represented by a red circle) and Al/CNT (represented by a blue square) resonators having a width of about 2 and about 3 μm, the about 50 nm Al and Al/CNTnt resonators having a width of about 2 μm, and the about 50 nm Al/CNTnt resonator having a width of about 3 μm, respectively. As shown in the drawings, in the case of l<˜20 μm for about 100 nm Al and Al/CNT doubly-clamped beams, the Al and Al/CNTnt resonators may be

$${f}_{o} ∝ \frac{1}{l} .$$

On the other hand, in the case of l>˜20 μm, the resonators may be

$${f}_{o} ∝ \frac{1}{{l}^{2}} .$$

For about 50 nm Al and Al/CNT doubly-clamped beams, when Equation 2 may be applied in the range of about 5 μm≦1≦about 50 μm, Al (circle) and Al/CNTnt (square) lines may be shown.

This consideration may be understood by the increased internal film stress (σᵢₙₜ) having a deposition time (linear thermal expansion coefficient of Al/GaAs ˜4.18) in the case of ωₒ∝L⁻¹. In the longer beam structure, σᵢₙₜ may be eliminated, as the structure may be very freely suspended. Thus, in order to determine the values of E and σᵢₙₜ from the about 100 nm Al and Al/CNTnt, applying Equation 2 may be difficult. Upon adjustment for about 50 nm Al and Al/CNTnt responses having E and σᵢₙₜ as the sole adjustment coefficients with a width of about 2 (and about 3) μm, in similar internal stress, E_{50nmAl/CNT}=224±15 GPa (280±51 GPa) and E_{50nmAl}=100±12 GPa (127±51 GPa): σᵢₙₜ^{50nmAl/CNT}=22 MPa±3 MPa (22 MPa±10 MPa) and σᵢₙₜ^{50nmAl}=15 MPa±2.5 MPa (18±4 MPa) or E_{Al/CNT}/E_{Al}≈2.2 and σᵢₙₜ^{Al/CNT}/σᵢₙₜ^{Al}≈1.3.

These dynamic flexural measurement values of fundamental response modes may be equal to about two times or more the value of effective E for the beam structure in which about 50 nm thick Al may be deposited on the CNTnt. In the case of the 100 nm thick Al sample, due to large σᵢₙₜ depending on L, it may be difficult to apply Equation 2 to E. In the decreased dimension, force spectroscopy using AFM cantilever tips was successfully applied to the determination of the mechanical properties of nanowires and nanorods. Hence, the quasi-static flexural measurement at the center of the beams may be used to quantitatively analyze E. The displacement at the center of the beams may be expressed as Z_{beam}=Z_{piezo}−Z_{deflection}, in which Z_{piezo} may be the MLGO movable distance in AFM and Z_{deflection} may be the deflection of the cantilever measured by the optical detector, and may be thus adjusted through measurement of the substrate (e.g., Z_{beam}=0).

From the gradient of the measurement values of force versus displacement on a beam (m_{beam}) and a substrate (m_{sub}) in the vicinity of the equilibrium position, Hook's law may be simply applied, and the spring constant

$${k}_{eff} = \frac{{m}_{beam} {m}_{sub}}{{m}_{sub} - {m}_{beam}}$$

may be deduced. From the geometrical structure of flexural loading and k_{eff},

$$E = \vert {k}_{eff} \vert \frac{{L}^{3}}{192 I}$$

results. For beams having L of about 8˜about 22 μm, from the quasi-static measurement coinciding with the dynamic flexural measurement value, E_{100nmAl/CNT}=212±58 GPa and E_{100nmAl}=about 135.88±50 GPa may be evaluated.

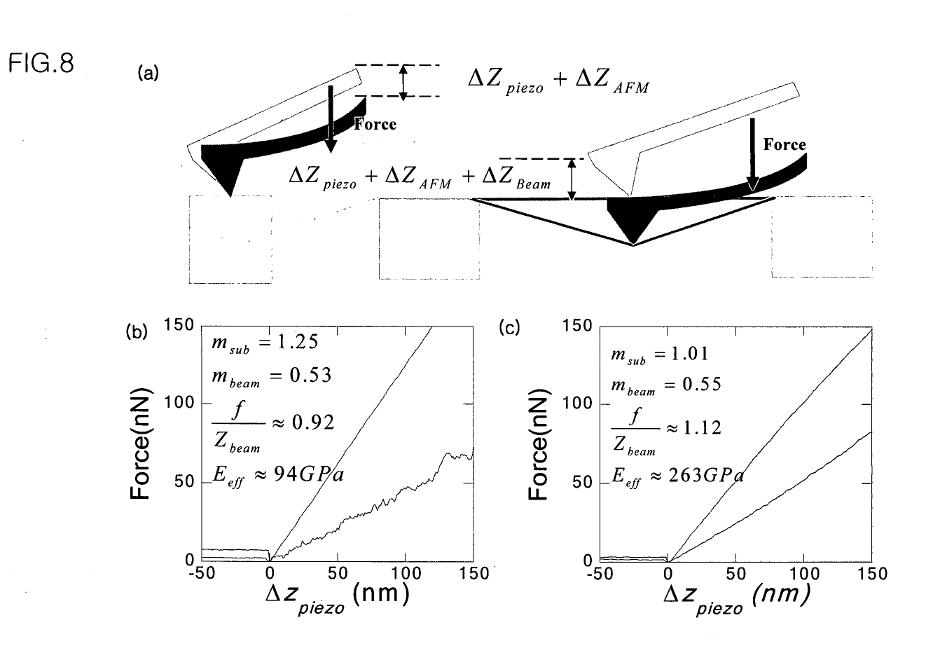

FIG. 8(a) schematically shows the force deflection spectroscopy, FIG. 8(b) shows the force deflection curve for Al beams (about 100 nm×about 3 μm×about 17 μm), and FIG. 8(c) shows the force deflection curve for Al/CNTnt beams (about 100 nm×about 3 μm×about 22 μm). All the gradients of the force deflection curves may be adjusted in the vicinity of Δz≈0.

As described hereinbefore, CNTs may be included, thus increasing the elastic modulus for metallic thin films and wires and improving yield strength and dynamic ranges. A free-standing micromechanical structure, which may be manufactured from a bilayer laminate through Al thin film deposition on a CNTnt and a manufacturing method thereof may be provided, and furthermore, as a specific example thereof, a doubly-clamped beam resonator may be provided. Thus, from dynamic flexural measurement, a fundamental resonance frequency, which may be uniformly high for given geometrical structures, may be obtained, and a bifurcation phenomenon for Al/CNTnt may be found, and also, continuum dynamics may be applied, thereby realizing means having a Young's modulus which may be doubled or more using the CNTnt.

Although example embodiments have been disclosed for illustrative purposes, those skilled in the art will appreciate that various modifications, additions and substitutions may be possible, without departing from the scope and spirit of the accompanying claims.

1. A free-standing metallic micromechanical structure comprising:
a metal thin film on a carbon nanotube network template.

2. The structure of claim 1, wherein the carbon nanotube network template is formed by laminating a self assembly of carbon nanotubes on a metal thin film having a thickness.

3. The structure of claim 2, wherein the self assembly of the carbon nanotubes is formed by sequentially laminating a single layer, a double layer and a triple layer, each of which has a thickness.

4. The structure of claim 1, wherein the carbon nanotube network template has a thickness of about 0.41 nm or less.

5. The structure of claim 1, wherein the metal thin film is formed of aluminum (Al).

6. A method of manufacturing a free-standing metallic micromechanical structure comprising:
forming a carbon nanotube network template on a substrate; and
forming a metal thin film on the carbon nanotube network template.

7. The method of claim 6, wherein forming the carbon nanotube network template includes self assembly of the carbon nanotube network template.

8. The method of claim 6, further comprising:
forming a pattern in a doubly-clamped beam form on the carbon nanotube network template, after forming the carbon nanotube network template on the substrate.

9. The method of claim 8, further comprising:
depositing a metal thin film, after forming the pattern in the doubly-clamped beam form on the carbon nanotube network template.

10. The method of claim 9, further comprising:
lifting off the metal thin film, after depositing the metal thin film.

11. The method of claim 10, further comprising:
forming suspended doubly-clamped beams, after lifting off the metal thin film.

12. The method of claim 11, further comprising:
forming a counter electrode through metal deposition, after forming the suspended doubly-clamped beams.

13. The method of claim 7, wherein the self assembly of the carbon nanotube network template includes:
depositing metal to a given thickness on the substrate;
placing the substrate in a solution of an o-dichlorobenzene solvent and single-walled carbon nanotubes having a given length;
removing the substrate from the solution; and
drying the substrate in liquid nitrogen.

14. The method of claim 13, wherein the self assembly of the carbon nanotube network template is repeated so as to form a single layer, a double layer, and a triple layer, each of which has a given thickness.

15. The method of claim 8, wherein the pattern in the doubly-clamped beam form has a given width and a given length and is formed on the carbon nanotube network template through e-beam lithography and photolithography.

16. The method of claim 12, wherein the counter electrode is formed using a wedge bonder to have a given thickness through metal deposition in order to electrically connect beams.

17. The method of claim 9, wherein the deposition is sputtering deposition.

18. A resonator structure comprising the micromechanical structure of claim 1.

19. The resonator structure of claim 18, wherein the resonator structure is a suspended doubly-clamped beam microresonator structure having a width of about 2˜about 3 μm and a length of about 5˜about 50 μm.

20. A method of manufacturing a resonator structure comprising:
manufacturing the free-standing metallic micromechanical structure according to the method of claim 6.

21. The structure of claim 1, wherein the metal thin film is laminated to a given thickness on the carbon nanotube network template.

22. The method of claim 6, wherein the substrate is a semiconductor substrate.
